(19) United States
(12) Patent Application Publication
(10) Pub. No.: US 2011/0012141 A1
(43) Pub. Date: Jan. 20, 2011

(54) SINGLE-COLOR WAVELENGTH-CONVERTED LIGHT EMITTING DEVICES

(76) Inventors: Ronan P. Le Toquin, Ventura, CA (US); George Brandes, Raleigh, NC (US)

Correspondence Address: MYERS BIGEL SIBLEY & SAJOVEC, P.A., P.O. BOX 37428, RALEIGH, NC, 27627, US

(21) Appl. No.: 12/503,695

(22) Filed: Jul. 15, 2009

(51) Int. Cl. H01L 33/00

(52) U.S. Cl. 257/89; 257/98; 257/E33.067; 257/E33.059

(57) ABSTRACT

A packaged light emitting device (LED) includes an LED chip configured to emit light within a first wavelength range, and a wavelength conversion material on the LED chip. The wavelength conversion material is configured to receive the light within the first wavelength range and responsively emit light within a second wavelength range different than the first wavelength range such that a light output of the packaged LED does not substantially include the light within the first wavelength range and provides an appearance of substantially monochromatic light of a color of the visible spectrum corresponding to the second wavelength range. The packaged LED may include a color filter on the wavelength conversion material that is configured to prevent passage of the light within the first wavelength range therethrough, and/or may include a thickness of the wavelength conversion material configured to completely absorb the light within the first wavelength range.

### FIELD

The present invention relates to semiconductor light emitting devices, and more particularly, to semiconductor light emitting devices including wavelength conversion materials.

### BACKGROUND

Light emitting diodes and laser diodes are well known solid state lighting elements capable of generating light upon application of a sufficient voltage. Light emitting diodes and laser diodes may be generally referred to as light emitting devices (“LEDs”). Light emitting devices generally include a p-n junction formed in one or more epitaxial layers grown on a substrate such as sapphire, silicon, silicon carbide, gallium arsenide and the like. When a bias is applied across the p-n junction, holes and/or electrons are injected into the active region. Recombination of holes and electrons in the active region generates light that can be emitted from the LED. The wavelength distribution of the light generated by the LED generally depends on the material from which the device, particularly the active region, is fabricated and the structure of the thin epitaxial layers that make up the active region of the device.

Typically, an LED chip includes an n-type epitaxial region and a p-type epitaxial region formed on the n-type epitaxial region (or vice-versa). In order to facilitate the application of a voltage to the device, an anode ohmic contact may be formed on a p-type region of the device (typically, an exposed p-type epitaxial layer) and a cathode ohmic contact may be formed on an n-type region of the device (such as a substrate or an exposed n-type epitaxial layer). The LED chip may include many additional layers to facilitate light generation and emission including (but not limited to) quantum wells, barrier layers, cladding layers and strain relief layers.

An LED chip may emit optical energy having a relatively narrow bandwidth, for example, having a full width at half maximum (FWHM)of about 17-30 nanometers (nm) or less. Accordingly, the light emitted by such an LED chip may be substantially monochromatic light that appears to have a single color. However, some such LEDs may be sensitive to thermal variation. For example, AlInGaP-based LEDs, which emit light in a wavelength range corresponding to the red portion of the visible spectrum, may experience significant changes in device efficiency and/or wavelength stability as drive current increases. This may result in reduced performance and/or operating lifetime of such LEDs.

### SUMMARY

According to some embodiments of the present invention, a packaged light emitting device (LED) includes an LED chip configured to emit light within a first wavelength range, and a wavelength conversion material on the LED chip. The wavelength conversion material is configured to receive the light within the first wavelength range and responsively emit light within a second wavelength range different than the first wavelength range and corresponding to a red portion of a visible spectrum, such that a light output of the packaged LED does not substantially include the light within the first wavelength range and provides an appearance of substantially monochromatic red light.

In some embodiments, the packaged LED may also include a color filter on the wavelength conversion material. The color filter may be configured to prevent passage of the light within the first wavelength range. Additionally or alternatively, the color filter may be configured to prevent passage of a portion of the light within the second wavelength range.

In other embodiments, the color filter may be provided as a layer on the wavelength conversion material such that the wavelength conversion material is between the color filter and the LED chip. The wavelength conversion material may be configured to absorb, reflect, and/or recycle at least a portion of the light within the first wavelength range, and the color filter may be configured to prevent passage of a remaining portion of the light within the first wavelength range that is not absorbed by the wavelength conversion material. The color filter and/or the wavelength conversion material may also be included in an encapsulant layer on the LED chip.

In some embodiments, the color filter and/or the wavelength conversion material may be spaced remotely from the LED such that the color filter and/or the wavelength conversion material are not in physical contact with the LED. The color filter and/or the wavelength conversion material may be spaced remotely and may be responsive to light from multiple LEDs.

In other embodiments, the color filter may be configured to prevent passage of at least some of the light within the second wavelength range, for example, to increase the degree or extent of monochromaticity of the light output of the packaged LED.

In some embodiments, the color filter may be a notch filter that is configured to absorb light having wavelengths greater than the second wavelength range and less than the second wavelength range.

In other embodiments, the wavelength conversion material may have a thickness that is configured to completely absorb the light within the first wavelength range.

In some embodiments, the wavelength conversion material may have a thickness of about 30 micrometers (μm) to about 75 μm. The thickness of the wavelength conversion material may also be selected to increase and/or maximize light emission at a desired wavelength or wavelengths within the second wavelength range, for example, to increase the degree or extent of monochromaticity of the light output of the packaged LED. In some embodiments, the wavelength conversion material may have a thickness of about 500 μm to about 5 millimeters (mm), for example, depending on the phosphor concentration per volume of the wavelength conversion material. Phosphor particles can be from 1 nm to 20 um in D50. Also, the color filter may be configured to block at least a portion of the light within the second wavelength range.

In some embodiments, the packaged LED may further include a second wavelength conversion material on the LED chip. The second wavelength conversion material may be configured to receive the light within the first wavelength range and responsively emit light within a third wavelength range different than the first wavelength range, such that the light output of the packaged LED may provide the appearance of the substantially monochromatic light of the color corresponding to the second and third wavelength ranges. For example, the first wavelength conversion material may be configured to absorb at least a portion of the light within the first wavelength range, and the second wavelength conversion material may be configured to absorb a remaining portion of the light within the first wavelength range that is not absorbed by the first wavelength conversion material. Alternatively, the second conversion material may be configured to absorb light over some or all of light within the second wavelength range emitted by the first conversion material.

In some embodiments, the wavelength conversion material may include a narrow emitter phosphor comprising at least one of Eu3+, Cr3+, and/or Mn2+/4+. In other embodiments, the wavelength conversion material may include a broadband emitter phosphor comprising at least one of Eu2+ and Ce3+. In still other embodiments, the wavelength conversion material may include a quantum dot comprising at least one of ZnS, ZnSe, CdS, and CdSe.

In other embodiments, the LED chip may include a Group III nitride-based active region, and the wavelength conversion layer may be a red-emitting phosphor, such that the light output of the packaged LED provides the appearance of light within a red portion of a visible spectrum. For example, the first wavelength range may include blue and/or ultraviolet light, and the wavelength conversion material may be at least one of (Ca,Sr,Ba)₂SiO₄:Eu2+, (Ca,Sr)SiAlN₃:Eu2+, CaSiN₂:Ce3+, CaSiN₂:Eu2+, (Sr,Ca)₂Si₅N₈:Eu2+, (Sr,Ca)S:Eu2+, Alpha and Beta SiAlON, and ZnGa₂S₄:Eu2+. Alternatively, the first wavelength range may include green light, and the wavelength conversion material may be CaSiN₂:Ce3+.

In some embodiments, the light output of the packaged LED may include at least some light within the first and/or second wavelength ranges that is not visible to the human eye.

According to other embodiments, of the present invention, a light emitting device (LED) includes an LED chip configured to emit primary light within a first wavelength range, a wavelength conversion material on the LED chip, and a color filter on the wavelength conversion material. The wavelength conversion material is configured to receive the primary light within the first wavelength range and responsively emit secondary light within a second wavelength range different than the first wavelength range.

In some embodiments, the color filter may be configured to prevent passage of the primary light within the first wavelength range therethrough. In other embodiments, the wavelength conversion material may be configured to absorb the primary light within the first wavelength range, and the color filter may be configured to prevent passage of at least some of the secondary light within the second wavelength range therethrough.

In some embodiments, the color filter may be configured to allow passage of the secondary light therethrough such that a light output of the LED provides an appearance of substantially monochromatic light of a color corresponding to the second wavelength range. Also, the light output of the packaged LED may not substantially include the primary light within the first wavelength range. For example, the wavelength conversion material may be configured to absorb at least a portion of the primary light within the first wavelength range, and the color filter may be configured to prevent passage of a remaining portion of the primary light within the first wavelength range that is not absorbed by the wavelength conversion material.

In other embodiments, the color filter may be configured to prevent passage of at least some of the secondary light, for example, to increase the degree or extent of monochromaticity of the light output of the packaged LED.

In some embodiments, the color filter may be a low pass filter that is configured to absorb light having wavelengths greater than that of the secondary light. In other embodiments, the color filter may be high pass filter that is configured to absorb light having wavelengths less than that of the secondary light. In still other embodiments, the color filter may be a notch filter that is configured to absorb light having wavelengths both greater than and less than that of the secondary light.

In other embodiments, the color filter may be a layer on the wavelength conversion material such that the wavelength conversion material is between the color filter and the LED chip. The color filter layer may also extend on opposing sidewalls of the LED chip. Furthermore, the color filter and/or the wavelength conversion material may be included in an encapsulant layer on the LED chip.

In some embodiments, the LED chip may include a GaN-based active region, and the wavelength conversion layer may be a red-emitting wavelength conversion material, such that the light output of the LED provides an appearance of light within a red portion of a visible spectrum.

In other embodiments, the LED chip may include a GaN-based active region, and the wavelength conversion layer may be a green-emitting wavelength conversion material, such that the light output of the LED provides an appearance of light within a green portion of a visible spectrum.

According to further embodiments of the present invention, a packaged light emitting device (LED) includes an LED chip comprising a GaN-based active region, and a wavelength conversion material on the LED chip. The LED chip is configured to emit primary light within a first wavelength range. The wavelength conversion material is configured to absorb the primary light emitted by the LED chip and responsively emit secondary light within a second wavelength range corresponding to a red portion of a visible spectrum, such that a light output of the packaged LED does not include the primary light within the first wavelength range and provides an appearance of substantially monochromatic red light.

In some embodiments, the packaged LED may also include a color filter on the wavelength conversion material. The color filter may be configured to prevent passage of the primary light within the first wavelength range. The color filter may also be configured to absorb at least some of the secondary light, for example, to increase the degree or extent of monochromaticity of the light output of the packaged LED. In some embodiments, the color filter may be a notch filter that is configured to absorb light having wavelengths both greater than and less than that of the secondary light.

In other embodiments, the wavelength conversion material may have a thickness that is selected to increase and/or maximize light emission at a desired wavelength or wavelength range.

According to still further embodiments of the present invention, a multi-chip light emitting device (LED) array includes a submount including first and second die mounting regions thereon, a first LED chip mounted on the first die mounting region and configured to emit light within a first wavelength range, and a second LED chip mounted on the second die mounting region and configured to emit light within a second wavelength range. A wavelength conversion material is provided on the first LED chip. The wavelength conversion material is configured to receive the light within the first wavelength range and responsively emit light within a third wavelength range different than the first wavelength range and corresponding to a red portion of a visible spectrum such that a light output therefrom does not substantially include the light within the first wavelength range, and provides an appearance of substantially monochromatic red light. An overall light output of the multi-chip LED array provides an appearance of white light.

### BRIEF DESCRIPTION OF THE DRAWINGS

FIGS. 1-3 are cross-sectional side views illustrating packaged light emitting devices according to some embodiments of the invention.

FIGS. 4A-D are cross-sectional views illustrating structures that may be used in light emitting device packages according to other embodiments of the invention.

FIG. 5 is a cross-sectional view illustrating a light emitting diode structure according to some embodiments of the invention.

FIG. 6A is a graph illustrating a representative light emission spectrum of a narrow emitter phosphor.

FIG. 6B is a graph illustrating a representative light emission spectrum of a packaged light emitting device according to some embodiments of the invention including the narrow emitter phosphor of FIG. 6A.

FIG. 7A is a graph illustrating a representative light emission spectrum of a broadband emitter phosphor.

FIG. 7B is a graph illustrating a representative light emission spectrum of a packaged light emitting device according to other embodiments of the invention including the broadband emitter phosphor of FIG. 7A.

FIG. 8A is a graph illustrating a representative transfer function of a UV/blue color filter and a representative light emission spectrum of a packaged light emitting device including the UV/blue color filter according to some embodiments of the invention.

FIG. 8B is a graph of a representative transfer function of a green color filter and a representative light emission spectrum of a packaged light emitting device including the green color filter according to some embodiments of the invention.

FIG. 9 is a graph illustrating efficiency vs. temperature characteristics of conventional light emitting devices as compared to light emitting devices according to some embodiments of the invention.

FIGS. 10A-10B are plan views illustrating examples of multi-chip LED arrays that may be used in light arrays according to some embodiments of the present invention.

FIG. 11 is an International Commission on Illumination (CIE) diagram illustrating examples of substantially monochromatic red light as output by packaged light emitting devices according to some embodiments of the present invention.

### DETAILED DESCRIPTION

The present invention now will be described more fully with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a layer, region or substrate is referred to as being “on” another element, it can be directly on the other element or intervening elements may also be present. For example, in some embodiments, air may be considered an intervening element. As such, the term “on” does not necessarily require physical contact between two elements. In contrast, when an element is referred to as being “directly on” another element, no intervening elements are present. Furthermore, relative terms such as “beneath” or “overlies” may be used herein to describe a relationship of one layer or region to another layer or region relative to a substrate or base layer as illustrated in the figures. It will be understood that these terms are intended to encompass different orientations of the device in addition to the orientation depicted in the figures. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the invention are described herein with reference to cross-sectional illustrations that are schematic illustrations of idealized embodiments of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, a region illustrated or described as a rectangle may have rounded or curved features due to normal manufacturing tolerances. Thus, the regions illustrated in the figures are schematic in nature and their shapes are not intended to illustrate the precise shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

As used herein, the term “semiconductor light emitting device” may include a light emitting diode, laser diode and/or other semiconductor device which includes one or more semiconductor layers, which may include silicon, silicon carbide, gallium nitride and/or other semiconductor materials. A light emitting device may or may not include a substrate such as a sapphire, silicon, silicon carbide, gallium nitride, and/or another microelectronic substrates. A light emitting device may include one or more contact layers which may include metal and/or other conductive layers. In some embodiments, ultraviolet, blue, and/or green light emitting diodes may be provided. The design and fabrication of semiconductor light emitting devices are well known to those having skill in the art and need not be described in detail herein.

For example, the semiconductor light emitting device may be gallium nitride-based LEDs or lasers fabricated on a silicon carbide substrate such as those devices manufactured and sold by Cree, Inc. of Durham, N.C. The present invention may be suitable for use with LEDs and/or lasers as described in U.S. Pat. Nos. 6,201,262; 6,187,606; 6,120,600; 5,912,477; 5,739,554; 5,631,190; 5,604,135; 5,523,589; 5,416,342; 5,393,993; 5,338,944; 5,210,051; 5,027,168; 5,027,168; 4,966,862 and/or 4,918,497. Other suitable LEDs are described in U.S. Pat. No. 6,958,497 entitled “Group III Nitride Based Light Emitting Diode Structures With a Quantum Well and Superlattice, Group III Nitride Based Quantum Well Structures and Group III Nitride Based Superlattice Structures,” and U.S. Pat. No. 6,791,119 entitled “Light Emitting Diodes Including Modifications for Light Extraction and Manufacturing Methods Therefor.” Furthermore, phosphor coated LEDs, such as those described in U.S. Pat. No. 6,853,010, entitled “Phosphor-Coated Light Emitting Diodes Including Tapered Sidewalls and Fabrication Methods Therefor,” may also be suitable for use in embodiments of the present invention. In some embodiments, the LEDs may be configured to operate such that light emission occurs through the substrate. In such embodiments, the substrate may be patterned so as to enhance light output of the devices as is described, for example, in the above-cited U.S. Pat. No. 6,791,119.

The term “phosphor” may be used herein to refer to any materials that absorb light at one wavelength and re-emit light at a different wavelength, regardless of the delay between absorption and re-emission and regardless of the wavelengths involved. Accordingly, the term “phosphor” may be used herein to refer to materials that are sometimes called fluorescent and/or phosphorescent. In general, phosphors absorb light having shorter wavelengths and re-emit light having longer wavelengths. As such, some or all of the excitation light emitted by an LED chip at a first wavelength may be absorbed by the phosphor particles, which may responsively emit light at a second wavelength. A fraction of the light may also be reemitted from the phosphor at essentially the same wavelength as the incident light, experiencing little or no down-conversion. As used herein, the “efficiency” of a phosphor may refer to the ratio of the photon output of the phosphor (at any wavelength) relative to the photon input to the phosphor, for example, from the LED chip. In contrast, the “efficiency” of a packaged LED may refer to the ratio of the overall light output by the LED to the electrical power input to the LED, which may be affected by the efficiency of the phosphor.

Some embodiments of the present invention arise from realization that LEDs that emit blue and/or ultraviolet (UV) light (such as blue and/or UV GaN-based LEDs) may offer significantly improved thermal stability and efficiency over LEDs that emit red light (such as red AlInGaP-based LEDs) as drive current increases. In particular, the efficiency of red AlInGaP-based LEDs may be greatly reduced when driven at higher current levels. Accordingly, some embodiments of the present invention provide packaged LEDs that emit red light by combining a GaN-based LED chip that emits UV, blue, or green light with at least one phosphor or other wavelength conversion material that emits red light. Particular phosphors may be excited by light in the green or blue wavelength ranges, while other phosphors may be excited by light in the UV or near-UV wavelength ranges. Examples of such phosphors include narrow emitters (such as Eu3+, Cr3+, and/or Mn2+/4+), and broadband emitters (such as Eu2+ and Ce3+). Also, semiconductor nanoparticles, or “quantum dots” (such as ZnS, ZnSe, CdS, and CdSe) may be used as a wavelength conversion material in some embodiments. Quantum dots may offer potential advantages over conventional phosphors as luminescent down-converting materials. For example, the emission spectra of quantum dots can be “tuned” by altering particle size distribution and/or surface chemistry, in contrast to phosphors, where the emission spectra may be fixed by nature. The term “wavelength conversion material” may be generally used herein to refer to any material or layer containing phosphors, quantum dots, and/or any other material that receives light at one wavelength and responsively re-emits light at a different wavelength.

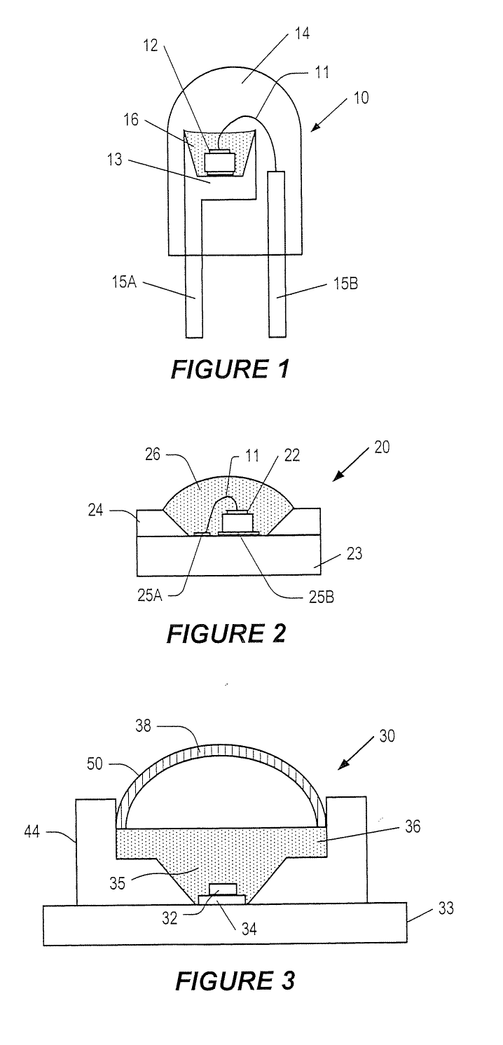

In order to use an LED chip in a circuit, the LED chip may be enclosed in a package to provide environmental and/or mechanical protection, color selection, focusing and the like. An LED package may also include electrical leads, contacts, and/or traces for electrically connecting the LED package to an external circuit. FIG. 1 illustrates an LED package 10 according to some embodiments of the present invention. As shown in FIG. 1, an LED chip 12 is mounted on a reflective cup 13 by means of a solder bond or conductive epoxy. One or more wirebonds 11 connect the ohmic contacts of the LED chip 12 to leads 15A and/or 15B, which may be attached to or integral with the reflective cup 13. The reflective cup may be filled with an encapsulant material 16 containing a wavelength conversion material, such as a phosphor. The entire assembly may be encapsulated in a clear protective resin 14, which may be molded in the shape of a lens to collimate the light emitted from the LED chip 12 and/or phosphor particles in the encapsulant material 16.

Still referring to FIG. 1, at least some of the light emitted by the LED chip 12 over a first wavelength range (also referred to herein as “primary light”) may be received by the phosphor, which may responsively emit light over a second wavelength range (also referred to herein as “secondary light”). The primary light emitted by the LED chip 12 may be partially or completely absorbed by the wavelength conversion material, such that the overall light output of the LED package 10 predominantly includes the secondary light emitted by the wavelength conversion material. For example, the primary light emitted by the LED chip 12 may be within the blue portion of the visible spectrum (e.g., about 440 nm to about 470 nm) or within the near-UV portion of the visible spectrum (e.g., about 380 nm to about 430 nm), and the phosphor may be selected to generate light in the red portion of the visible spectrum (e.g., about 590 nm to about 750 nm) in response to stimulation by the primary light. The resulting light emitted by the package 10 may not substantially include the primary light emitted by the LED chip 12, and may therefore appear to be red to an observer. More generally, the package 10 may appear to emit substantially monochromatic light of a color that is different from that of the primary light emitted by the LED chip 12.

As used herein, “substantially monochromatic” light may refer to light that provides an appearance of light corresponding to a single color of the visible spectrum. For example, substantially monochromatic red light may predominantly include light with wavelengths of about 590 nm to about 750 nm, but may also include at least some light having wavelengths outside of this range. In particular, packaged LEDs according to some embodiments may output substantially monochromatic red light having a wavelength range of about 590 nm to about 660 nm, and a full width at half maximum (FWHM) of less than about 90 nm to about 100 nm. Such packaged LEDs may use Eu-doped Sr₂₋ₓBaₓSiO4 (BOSE) as a wavelength conversion material. Packaged LEDs according to some embodiments may also output substantially monochromatic red light having a wavelength range of about 590 nm to about 650 nm (in particular embodiments, about 615 nm to about 645 nm) and a FWHM of less than about 90 nm. Such packaged LEDs may use a nitride-based phosphor as a wavelength conversion material.

FIG. 11 is a CIE color space chromaticity diagram including a box (shown by dotted line 1110) representing color coordinates corresponding to substantially monochromatic red light emitted by packaged LEDs according to some embodiments of the present invention. In some embodiments, the substantially monochromatic red light output may include a dominant emission peak in the red wavelength range, as well as an emission peak in the blue wavelength range. The lines 1120 and 1130 illustrate the color points for output light from a blue-emitting LED chip using, for example, one BOSE composition and one nitride-based red phosphors (Ca,Sr)AlSiN3:Eu2+, respectively, as wavelength conversion materials. It should be noted that the lines 1120 and 1130 can be moved by modifying/altering the chemical composition of these two examples. The particular wavelength ranges, subranges, and/or emission peaks of the substantially monochromatic red light emitted by packaged LEDs according to some embodiments of the present invention may depend on which of the particular wavelength conversion materials (such as those described herein) are used.

Another LED package 20 according to some embodiments of the present invention is illustrated in FIG. 2. The package of FIG. 2 may be more suited for high power operations which may generate more heat. In the LED package 20, an LED chip 22 is mounted onto a carrier, such as a printed circuit board (PCB) carrier 23. A metal reflector 24 mounted on the carrier 23 surrounds the LED chip 22 and reflects light emitted by the LED chip 22 away from the package 20. The metal reflector 24 is typically attached to the carrier 23 by means of a solder or epoxy bond. The reflector 24 also provides mechanical protection to the LED chip 22. One or more wirebond connections 11 are made between ohmic contacts on the LED chip 22 and electrical traces 25A, 25B on the carrier 23. The mounted LED chip 22 is covered with an encapsulant 26, which may provide environmental and/or mechanical protection to the chips while also acting as a lens. The encapsulant 26 includes a phosphor that absorbs at least some of the light emitted by the LED chip 22, and responsively emits light of a different wavelength.

The thickness of the phosphor (or other wavelength conversion material) layer may be selected such that the excitation wavelengths of the primary light emitted by the LED chip 22 are completely absorbed by the phosphor in some embodiments. For example, the phosphor or other wavelength conversion material may have a thickness of about 30 micrometers (μm) to about 75 μm. Phosphors in accordance with some embodiments of the present invention may be excited in the near-UV wavelength range (e.g., about 380 nm to about 430 nm) and/or the blue wavelength range (e.g., about 440 nm to about 470 nm). In particular embodiments, phosphors having a peak efficiency when excited by light of about 400 nm may be used. In other embodiments, the encapsulant 26 may also be selected to act as a color filter that prevents passage of wavelengths of the light emitted by the LED chip 22 that are not absorbed by the phosphor. The thickness of the phosphor may thereby be selected to provide enhanced efficiency, and need not absorb all of the primary light from the LED chip 22. The thickness of the wavelength conversion material may also be selected to increase and/or maximize light emission at a desired wavelength or wavelengths, for example, to increase the degree or extent of monochromaticity of the light output of the LED package 20. Accordingly, the overall light output of the LED package 20 provides substantially monochromatic light as emitted by the phosphor, and does not substantially include the light emitted by the LED chip 22.

Yet another LED package 30 according to some embodiments of the present invention is illustrated in FIG. 3. As shown in FIG. 3, an LED package 30 includes an LED chip 32 mounted on a submount 34 to a carrier substrate 33. The carrier substrate 33 can include an alumina substrate and/or a metal core PCB carrier substrate. A reflector 44 attached to the carrier substrate 33 surrounds the LED chip 32 and defines an optical cavity 35 above the LED chip(s) 32. An encapsulant material 36, such as silicone, fills the optical cavity 35.

The reflector 44 reflects light emitted by the LED chip 32 away from the package 30. The reflector 44 also includes an upwardly extending cylindrical sidewall 45 that defines a channel in which a lens 50 can be inserted. The lens 50 is held in place by the encapsulant material, and can move up and down as the encapsulant material 36 expands and contracts due to heat cycling. The lens 50 may include a light-scattering lens that is configured to refract light emitted by the LED and the wavelength conversion material. In some embodiments, the light scattering lens is configured to scatter the emitted light randomly. The light-scattering can include a transparent lens body including light scattering particles such as TiO₂, Al₂O₃, SiO₂, etc. in the lens body and/or the lens can include a roughened outer surface that can randomly scatter light that exits the lens 50.

The encapsulant material 36 further includes a phosphor (or other wavelength conversion material) therein. The phosphor included in the encapsulant material 36 is configured to receive the primary light emitted by the LED chip 32, and responsively emit secondary light over a wavelength range that is different from that of the primary light. In addition, a color filter layer 38 is provided on the wavelength conversion layer to filter portions of the primary light emitted by the LED chip 32 that are not absorbed by the phosphor, such that the overall light output of the LED 30 does not include the primary light emitted by the LED chip 32.

In particular, as shown in FIG. 3, the color filter layer 38 is provided on an inner surface of the lens 50, such that the encapsulant material 36 including the phosphor therein is between the color filter layer 38 and the LED chip 32. The color filter layer 38 is configured to prevent or block passage of the primary light emitted by the LED chip 32 (at least to a level undetectable by the naked human eye) and/or passage of at least some of the secondary light emitted by the LED chip 32 (to a level appropriate for the intended LED application), such that the overall light output of the LED package 30 includes only the secondary light emitted by the phosphor or other wavelength conversion material included in the encapsulant 36. For example, the color filter layer 38 may be low pass filter that is configured to absorb light having wavelengths greater than some or all of the secondary light emitted by the phosphor or other wavelength conversion material included in the encapsulant 36. Additionally or alternatively, the color filter layer 38 may be high pass filter that is configured to absorb light having wavelengths less than some or all of the secondary light emitted by the phosphor or other wavelength conversion material included in the encapsulant 36. In further embodiments, the color filter layer 38 may be a notch filter that is configured to pass only some of the light emitted by the phosphor or other wavelength conversion material included in the encapsulant 36 to provide light emission having a peak at a desired wavelength or over a desired wavelength range. Due to the presence of the color filter 38, the phosphor or other wavelength conversion material included in the encapsulant 36 need not completely absorb the primary light emitted by the LED chip 32. As such, the thickness of the encapsulant material layer 36 in FIG. 3 may be selected to provide improved LED/phosphor conversion efficiency and/or light emission at a desired wavelength or wavelengths to increase the degree of monochromaticity of the light output of the LED package 30. For example, the encapsulant material layer 36 including the phosphor therein may have a thickness of about 30 μm to about 50 μm. The thickness of the encapsulant material 36 may also be selected based on the phosphor concentration per volume of the encapsulant material 36. For example, in some embodiments, the encapsulant material layer 36 may have a thickness of about 500 μm to about 5 mm or less. The color filter layer 38 may also be configured to prevent passage of at least some of the light emitted by the phosphor or other wavelength conversion material included in the encapsulant 36, for example, to increase the degree of monochromaticity of the light output of the LED package 30.

Although described above with reference to an encapsulant solution containing phosphor particles, it is to be understood that other wavelength conversion materials, such as quantum dots, may be used in the embodiments of FIGS. 1-3 to provide the light conversion described above. Also, while described above with reference to only a single phosphor, it is to be understood that two or more phosphors, quantum dots, and/or other wavelength conversion materials may be included in the encapsulant material, and may collectively provide the light conversion described above. Moreover, the thicknesses and/or types of phosphors may be selected such that the phosphors, in combination, substantially or even completely absorb the primary light emitted by the LED chip. For example, a first wavelength conversion material or layer on an LED chip may be configured to absorb some of the primary light emitted by the LED chip, and a second wavelength conversion material or layer on the LED chip may be configured to absorb the remainder of the primary light that is not absorbed by the first wavelength conversion material. The second wavelength conversion material may also be configured to absorb some or all of the light emitted by the first conversion material in some embodiments.

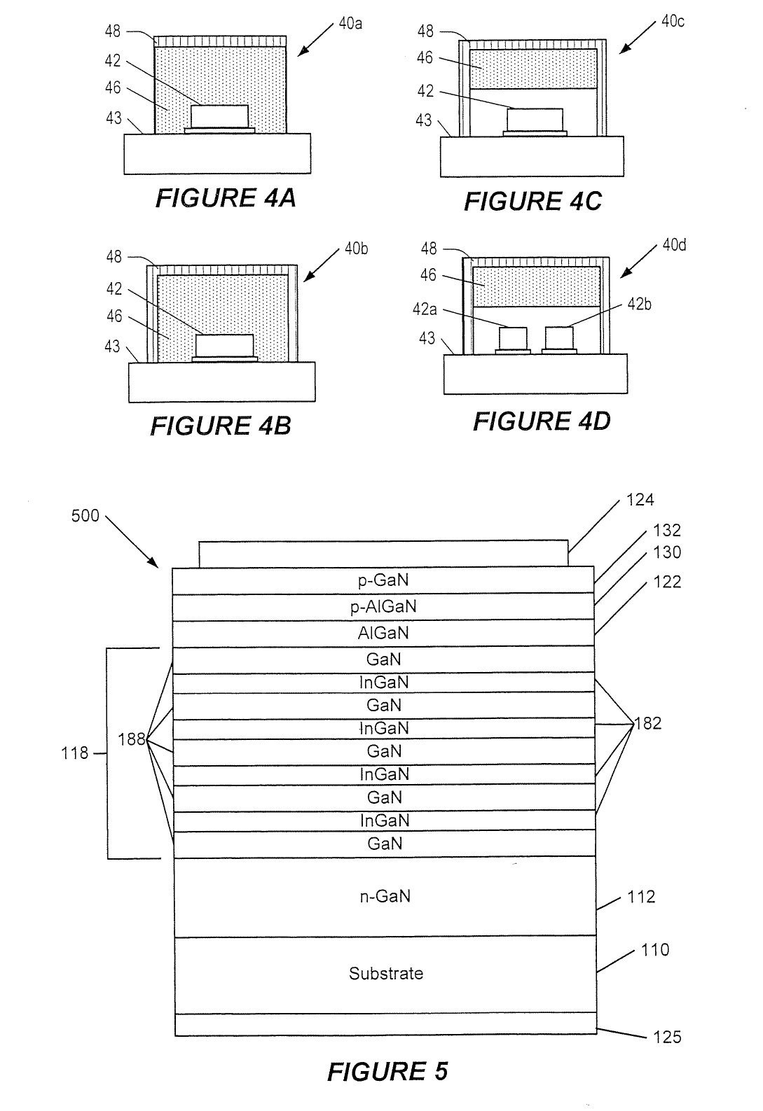

FIGS. 4A-D illustrate further LED structures in accordance with some embodiments of the present invention. As shown in FIG. 4A, an LED 40a includes a wavelength conversion layer 46 on an LED chip 42. The wavelength conversion layer 46 is configured to receive the primary light emitted by the LED chip 42 and responsively emit secondary light of a different wavelength. A color filter layer 48 is provided as an intermediate layer on the wavelength conversion layer 46, such that the wavelength conversion layer 46 is between the color filter layer 48 and the LED chip 42. As such, the color filter layer 48 is configured to block passage of the primary light from the LED chip 42 that is emitted away from the carrier substrate 43 (or prevent passage of the primary light at least to a level that is undetectable by the naked human eye), but allow passage of the secondary light responsively emitted by the wavelength conversion layer 46, such that the overall light output of the LED 40a does not substantially include the primary light.

FIG. 4B illustrates a similar LED 40b, where the color filter layer 48 further extends on the sides of the wavelength conversion layer 46. As such, the color filter layer 48 may also prevent the passage or transmission of portions of the primary light emitted by the LED chip 42 that are not absorbed by the wavelength conversion layer 46 at the sides of the LED chip 42. FIG. 4C illustrates yet another LED configuration 40c, where the wavelength conversion layer 46 is provided on a surface of the LED chip 42 opposite the carrier substrate 43 to receive the primary light emitted therefrom and responsively emit the secondary light of a different wavelength. The color filter layer 48 extends on the upper surface of the wavelength conversion layer 46 and on the sides of the LED chip 42 to prevent passage of portions of the primary light emitted by the LED chip 42 that are not absorbed by the wavelength conversion layer 46 in a direction away from the carrier substrate 43, as well as to block transmission of portions of the primary light output at the sides of the LED chip 42. FIG. 4C further illustrates an LED 40c where both the wavelength conversion layer 46 and the color filter layer 48 are remote from (e.g., not in physical contact with) the LED chip 42. For example, another optically transparent layer, or even air, may be provided between the LED chip 42 and the wavelength conversion layer 46 and/or the color filter layer 48. FIG. 4D illustrates that multiple LED chips 42a and 42b may be provided in an LED 40d in some embodiments.

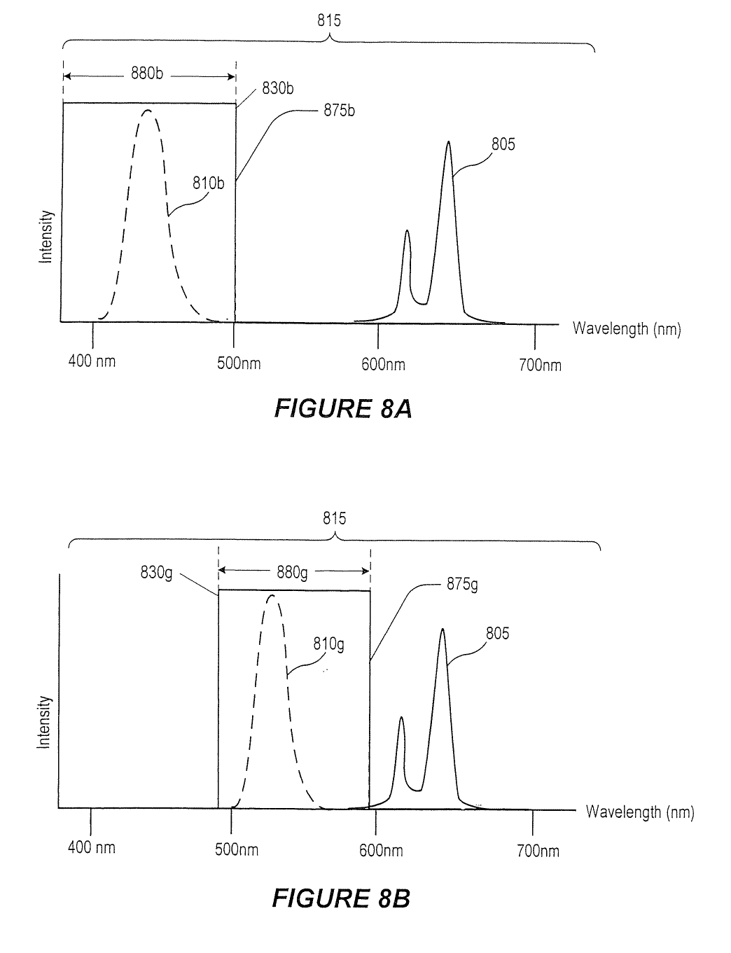

The color filter layers described above with reference to FIGS. 3 and 4A-C may be configured to prevent passage of light having wavelengths of about 595 nm or less, and allow passage of light having wavelengths of about 600 nm or more in some embodiments. The transfer functions of such color filters are described in detail below with reference to FIGS. 8A-B. Also, in some embodiments, the overall light output of the packaged LED may be within a bandwidth of less than about 50 nm. In other embodiments, the overall light output of the packaged LED may have a bandwidth of less than about 150 nm.

An exemplary epitaxial structure of an LED chip that can be used to generate the primary excitation light in accordance with embodiments of the invention is illustrated in FIG. 5. In particular, FIG. 5 illustrates a light emitting diode (LED) structure 500. The LED structure 500 of FIG. 5 is a layered semiconductor structure including gallium nitride-based semiconductor layers on a substrate 110. The substrate 110 is preferably 4H or 6H n-type silicon carbide, but can also include sapphire, silicon, bulk gallium nitride or another suitable substrate. In some embodiments, the substrate can be a growth substrate on which the epitaxial layers of the LED structure 500 are formed. In other embodiments, the substrate 110 can be a carrier substrate to which the epitaxial layers are transferred. For example, the substrate 110 can include silicon, alumina, or any other suitable material that provides appropriate mechanical, electrical and/or optical properties. In some embodiments, the substrate can be removed altogether, as is known in the art.

As shown in FIG. 5, the LED structure 500 includes an n-type silicon-doped GaN layer 112 on the substrate 110. One or more buffer layers (not shown) may be formed between the substrate 110 and the GaN layer 112. Examples of buffer layers between silicon carbide and Group III-nitride materials are provided in U.S. Pat. Nos. 5,393,993, 5,523,589, and 6,459,100. Similarly, embodiments of the present invention may also include structures such as those described in U.S. Pat. No. 6,201,262 entitled “Group III Nitride Photonic Devices on Silicon Carbide Substrates With Conductive Buffer Interlay Structure.”

An n-type superlattice structure (not shown), can be formed on the GaN layer 112. Suitable n-type superlattice structures are described, for example, in U.S. Pat. No. 6,958,497, assigned to the assignee of the present invention. The active region 118 may be a multi-quantum well structure, as described in greater detail below. An undoped GaN and/or AlGaN layer 122 is on the active region 118, and an AlGaN layer 130 doped with a p-type impurity is on the undoped layer 122. A GaN contact layer 132, also doped with a p-type impurity, is on the AlGaN layer 130. The structure further includes an n-type ohmic contact 125 on the substrate 110 and a p-type ohmic contact 124 on the contact layer 132.

The undoped layer 122 on the active region 118 can be undoped GaN or AlGaN between about 0 and 120 Å thick inclusive. As used herein, “undoped” refers to material that is not intentionally doped with a dopant ion either during growth or afterwards, such as by ion implantation or diffusion. The level of aluminum in the undoped layer 122 may also be graded in a stepwise or continuously decreasing fashion. The undoped layer 122 may be grown at a higher temperature than the growth temperatures in quantum well region 118 in order to improve the crystal quality of the undoped layer 122. Additional layers of undoped GaN or AlGaN may be included in the vicinity of the undoped layer 122.

The active region 118 comprises a multi-quantum well structure that includes multiple InGaN quantum well layers 182 separated by barrier layers 188. The barrier layers 188 can include InₓGa₁₋ₓN where 0≦x<1. The indium composition of the barrier layers 188 can be less than that of the quantum well layers 182, so that the barrier layers 188 have a higher bandgap than quantum well layers 182. The barrier layers 188 and quantum well layers 182 may be undoped (i.e., not intentionally doped with an impurity atom such as silicon or magnesium). In further embodiments of the present invention, the barrier layers 188 may be AlₓIn_{Y}Ga_{1-x-y}N where 0<x<1, 0≦y<1 and x+y≦1. By including aluminum in the crystal of the barrier layers 188, the barrier layers 188 may be lattice-matched to the quantum well layers 182, thereby providing improved crystalline quality in the quantum well layers 182, which can increase the luminescent efficiency of the device. The structure of the active region 118 including the quantum well layers 182 and the barrier layers 188 can be as described, for example, in U.S. Pat. No. 6,958,497.

The wavelength of light output by the LED structure 500 can be affected by many different growth parameters of the active region 118, including the thickness, composition and growth temperature of the quantum well layers 182. In particular, the indium composition of the quantum well layers 182 has a strong influence on the wavelength of light output by the structure. The more indium that is included in a quantum well 182, the longer the wavelength of light that will be produced by the well. For example, an indium concentration of about 10% to about 27% may produce blue light, while an indium concentration of about 28% to about 35% may produce green light. Also, while illustrated in FIG. 5 with reference to an active region including gallium nitride (GaN)-based layers, it is to be understood that other Group III nitride semiconductor-based layers may be used to provide LED chips in accordance with some embodiments of the present invention.

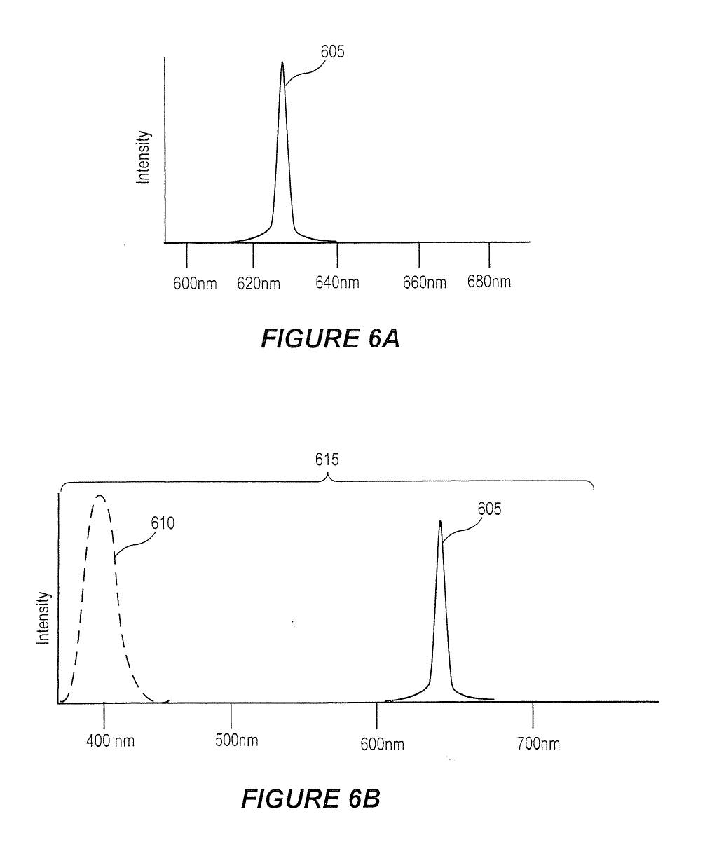

FIG. 6A is a graph illustrating a representative light emission spectrum 605 for a narrow emitter phosphor that may be used in LEDs according to some embodiments of the present invention. That is, the light emission spectrum 605 shows the secondary light that is output by a narrow emitter phosphor in response to excitation by primary light from an LED chip. As used herein, the term “narrow emitter” refers to a phosphor that responsively emits monochromatic light having a bandwidth of less than about 5 nm to about 10 nm, and a spectral distribution with a full width at half maximum (FWHM) of less than about 3 nm to about 5 nm. Examples of such phosphors include Eu3+, Cr3+, and/or Mn2+/4+ doped phosphors. Narrow emitter phosphors may be used to provide improved color purity and/or higher conversion efficiency in some embodiments. As shown in FIG. 6A, the light emission spectrum 605 of the narrow emitter phosphor includes a peak in the red portion of the visible spectrum, which can be located, for example, from about 600 nm to about 660 nm. The light emission spectrum 605 is plotted as intensity versus wavelength, where the intensity is shown in arbitrary units.

FIG. 6B is a graph of a representative light emission spectrum 615 of a packaged LED including the narrow emitter phosphor of FIG. 6A. In the light emission spectrum 615, primary light 610 emitted by an LED chip in the near-UV wavelength range (e.g., about 380 nm to about 430 nm) is absorbed by the narrow emitter phosphor and is re-emitted as secondary light 605 in the red wavelength range (e.g., about 590 nm to about 750 nm), such that the overall light output 615 of the LED package provides an appearance of monochromatic, narrowband light (e.g., having a bandwidth of less than about 50 nm) corresponding to the red portion of the visible spectrum, and does not include the primary light 610 emitted by the LED chip. More particularly, as shown in FIG. 6B, the primary light 610 emitted by the LED chip is completely absorbed by the narrow emitter phosphor, which responsively emits the secondary light 605 with a relatively high efficiency. For example, the narrow emitter phosphor may be a red Eu3+ doped phosphor, which may provide a relatively high internal efficiency of about 95% or more. Other examples of UV excitable narrow emitter phosphors include (Y,Bi)VO₄:Eu3+, (Bi,Ln)VO4:Eu3+, Y₂O₂S:Eu3+, Y₂O₃:Eu3+, and/or ZnGa₂S₄:Mn2+. The thickness of the narrow emitter phosphor may be selected to completely absorb the primary excitation light 610 provided by the LED chip. However, in other embodiments, portions of the primary light 610 that are not absorbed by the phosphor may be blocked by a color filter to provide the overall light emission spectrum 615 that does not substantially include the primary light 610. In such embodiments, the thickness of the phosphor may be selected to enhance efficiency, rather than to completely absorb the excitation light 610 from the LED chip. Also, although FIGS. 6A and 6B illustrate the use of only a single narrow emitter phosphor, it is to be understood that two or more phosphors that responsively emit light within the red portion of the visible spectrum may be provided in a single packaged LED in some embodiments.

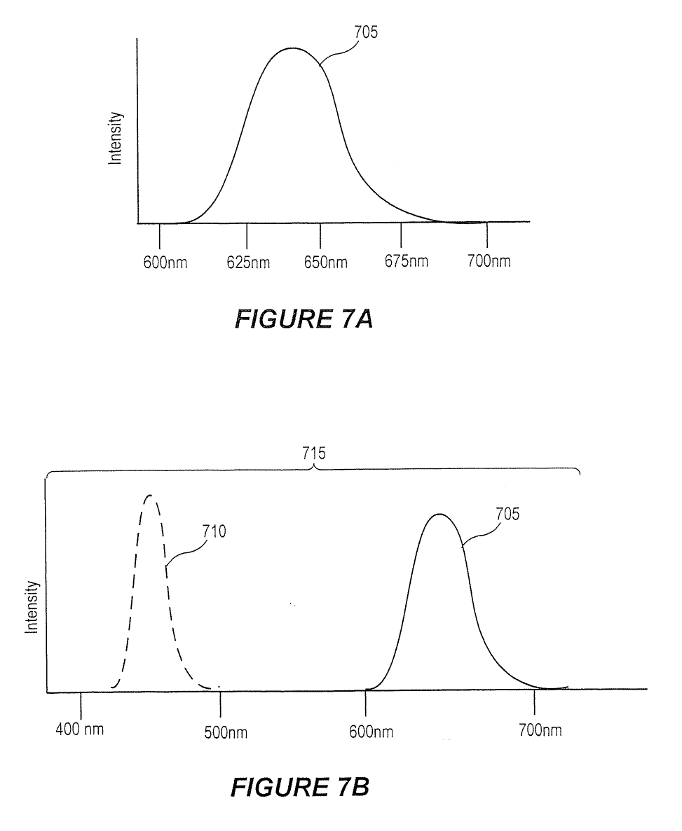

FIG. 7A is a graph illustrating a representative light emission spectrum 705 for a broadband emitter phosphor that may be used in LEDs according to some embodiments of the present invention. That is, the light emission spectrum 705 shows the secondary light output by a broadband emitter phosphor in response to excitation by primary light from an LED chip. As used herein, the term “broadband emitter” refers to a phosphor that responsively emits monochromatic light having a bandwidth of less than about 50 nm to about 100 nm or more. Examples of such phosphors include Eu2+ and Ce3+ doped phosphors. Other examples of blue and/or UV excitable broadband emitters include (Ca,Sr,Ba)₂SiO₄:Eu2+, (Ca,Sr)SiAlN₃:Eu2+, (Ca,Ba,Sr)2Si5N8:Eu2+, alpha, beta SiAlON doped with either Ce3+ and Eu2+, CaSiN₂:Ce3+, CaSiN₂:Eu2+, (Sr,Ca)₂Si₅N₈:Eu2+, (Sr,Ca)S:Eu2+, and/or ZnGa₂S₄:Eu2+. Some broadband emitters may emit light having a bandwidth of less than about 80 nm to about 100 nm. As shown in FIG. 7A, the light emission spectrum 705 of the broadband emitter phosphor includes a peak in the red portion of the visible spectrum, which can be located, for example, from about 600 nm to about 700 nm. The light emission spectrum 705 of FIG. 7A is plotted as intensity versus wavelength, where the intensity of the light emission spectrum is shown in arbitrary units.

FIG. 7B is a graph of a representative light emission spectrum 715 of a packaged LED including the broadband emitter phosphor of FIG. 7A. In the light emission spectrum 715, primary light 710 emitted by an LED chip in the blue wavelength range (e.g., about 440 nm to about 470 nm) is absorbed by the broadband emitter phosphor and is re-emitted as secondary light 705 in the red wavelength range (e.g., about 590 nm to about 750 nm), such that the overall light output 715 of the LED package provides an appearance of monochromatic light corresponding to the red portion of the visible spectrum, and does not include the primary light 710 emitted by the LED chip. More particularly, as shown in FIG. 7B, the primary light 710 emitted by the LED chip is completely absorbed by the broadband emitter phosphor, which responsively emits the secondary light 705 with a relatively high efficiency. The thickness of the broadband emitter phosphor may be selected to completely absorb the primary excitation light 710 provided by the LED chip. However, in other embodiments, portions of the primary light 710 that are not absorbed by the phosphor may be blocked by a color filter to provide the overall light emission spectrum 715 that does not include the primary light 710. In such embodiments, the thickness of the phosphor may be selected to enhance efficiency, rather than to completely absorb the excitation light 710 from the LED chip.

FIGS. 8A and 8B illustrate representative transfer functions for color filters that may be used in packaged LEDs according to some embodiments of the present invention to prevent the passage of the primary excitation light emitted by the LED chips therein. Referring to FIG. 8A, a UV/blue color filter is configured to allow passage of red light, but prevent passage of blue and/or UV light, as illustrated by transfer function 830b. The cutoff wavelength 875b of the UV/blue color filter is provided above the maximum wavelength of the blue or UV light that is to be blocked, but below the minimum wavelengths of the red light that is to be transmitted. Also, the bandwidth 880b of the UV/blue color filter is selected to prevent passage of light in the UV, near-UV, and blue wavelength ranges, which may be emitted by a blue and/or UV LED chip. In particular, the transfer function 830b is configured to allow the passage of light having wavelengths of greater than about 500 nm, but prevent the passage of light having wavelengths of about 500 nm or less. Accordingly, as shown in FIG. 8A, the primary light 810b emitted by a blue LED chip may be partially absorbed by one or more phosphors (such as Y₂O₂S:Eu2+) that responsively emit secondary light 805 in the red portion of the visible spectrum, and portions of the primary light that are not absorbed by the phosphor(s) are blocked by the UV/blue color filter. The two “peaks” of the secondary light 805 illustrated in FIGS. 8A and 8B may be provided by two narrow emitter phosphors; however, it is to be understood that fewer or more phosphors (and/or other wavelength conversion materials) may be used in some embodiments. Thus, the overall light output 815 of the packaged LED provides an appearance of light corresponding to the red portion of the visible spectrum, and does not include the primary light 810b emitted by the blue LED chip.

Similarly, as shown in FIG. 8B, a green color filter may be configured to allow passage of red light, but prevent passage of green light, as illustrated by transfer function 830g. The cutoff wavelength 875g of the green color filter is provided above the maximum wavelength of the green light to be blocked, but below the minimum wavelengths of the red light to be transmitted. Also, the bandwidth 880g of the green color filter is selected to prevent passage of light in the green wavelength ranges, which may be emitted by a green LED chip. In particular, the transfer function 830g is configured to allow the passage of light of wavelengths greater than about 595 nm or less than about 480 nm, but prevent the passage of light of wavelengths within the range of about 480 nm to about 595 nm. Accordingly, as shown in FIG. 8B, the primary light 810g emitted by a green LED chip may be partially absorbed by one or more phosphors (such as CaSiN₂:Ce3+) that responsively emit secondary light 805 in the red portion of the visible spectrum, and portions of the primary light that are not absorbed by the phosphor(s) are blocked by the green color filter. Thus, the overall light output 815 of the LED package provides an appearance of light corresponding to the red portion of the visible spectrum, and does not include the primary light 810g emitted by the green LED chip.

Accordingly, the color filters of FIGS. 8A and 8B may be used with a GaN-based LED chip and a red-emitting phosphor to allow passage of the red light responsively emitted by the phosphor, but prevent passage of the excitation light emitted by the LED chip that is not absorbed by the phosphor. Packaged LEDs according to some embodiments of the present invention may thereby provide substantially monochromatic output light 815 in the red wavelength range that does not include the primary light emitted by the LED chips therein. It is to be understood that the transfer functions 830b and 830g illustrated in FIGS. 8A and 8B represent idealized embodiments of the invention. As such, variations from the shapes of the illustrated transfer functions are to be expected. For example, regions of the transfer functions 830b and 830g illustrated or described as being rectangular will, typically, have rounded or curved features. Thus, the transfer functions 830b and 830g illustrated in the figures are not intended to illustrate the precise shape of such transfer functions, and are not intended to limit the scope of the invention.

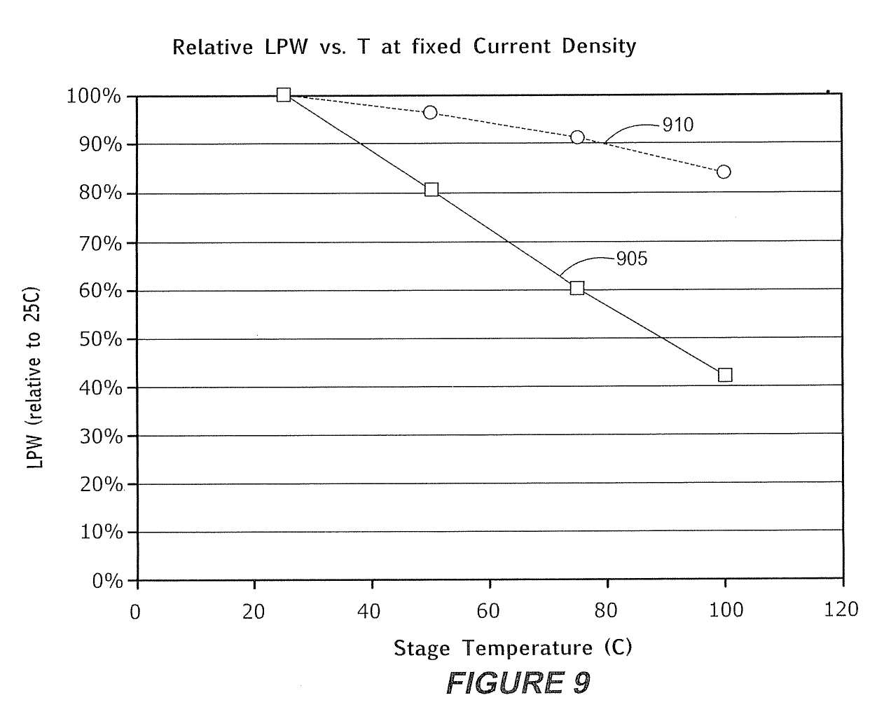

FIG. 9 is a graph illustrating the efficiency (in lumens per watt) vs. temperature characteristics of conventional red AlInGaP-based LED 905 as compared to a red phosphor converted GaN-based LED 910 according to some embodiments of the present invention. As illustrated in FIG. 9, the conversion losses in a such a red phosphor-converted GaN-based LED 910 can be significantly lower than the loss in efficiency of a direct red AlInGaP LED 905 as operating temperature increases.

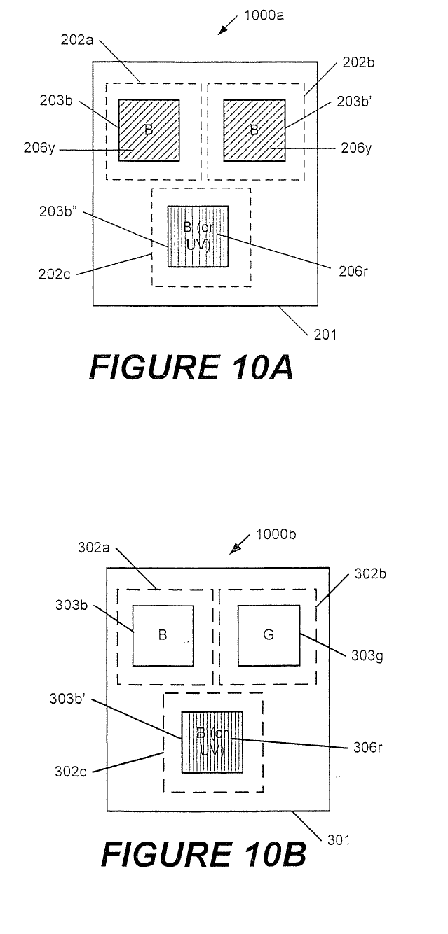

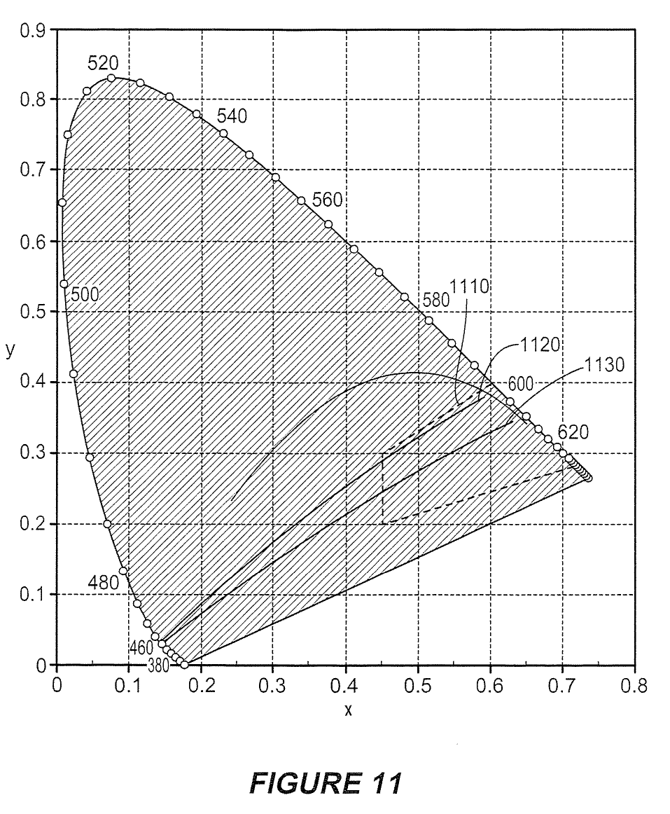

FIGS. 10A-10B illustrate examples of multi-chip LED arrays that may be used in light arrays according to some embodiments of the present invention. Referring now to FIG. 10A, a multi-chip LED array 1000a includes a common substrate or submount 201 having three die mounting regions 202a, 202b, and 202c. Three LED chips 203b, 203b′, and 203b″ are mounted on the die mounting regions 202a, 202b, and 202c, respectively. In some embodiments, the LED chips 203b, 203b′, and 203b″ may be vertical devices including a cathode contact on one side the chip and an anode contact on an opposite side of the chip. The LED chips 203b and 203b′ may be configured to emit light within the blue wavelength range, while the LED chip 203b″ may be configured to emit light within blue and/or ultraviolet wavelength ranges.

A yellow-emitting phosphor 206y at least partially covers the blue LED chips 203b and 203b′, while a red-emitting phosphor 206r at least partially covers the blue LED chip 203b″. For example, the yellow-emitting phosphor 206y may include yttrium aluminum garnet (YAG) crystals which have been powdered and/or bound in a viscous adhesive. The yellow-emitting phosphor 206y may be configured to exhibit luminescence when photoexcited by the blue light emitted from the blue LED chips 203b and 203b′. In other words, the yellow-emitting phosphor 206y is configured to absorb at least a portion of the light emitted by the blue LED chips 203b and 203b′ and re-emit light in a yellow wavelength range (e.g., about 570 nm to about 590 nm), such that the overall light output of the phosphor-converted blue LED chips 203 and 203′ provides the appearance of white light.

The red-emitting phosphor 206r is configured to absorb the light emitted by the LED chip 203b″ and re-emit light in a red wavelength range (e.g., about 590 nm to about 750 nm), such that the overall light output of the phosphor-converted LED chip 203b″ does not substantially include the light emitted by the LED chip 203b″ and provides the appearance of substantially monochromatic red light. For example the red-emitting phosphor 206r may be Y₂O₂S:Eu2+ in some embodiments. A color filter (not shown) may also be provided on the LED chip 203b″ to block light emitted therefrom that is not absorbed and/or converted to light within the red wavelength range by the phosphor 206r. As such, the combination of light emitted by the three LED chips 203b, 203b′, and 203b″ and the light emitted by the phosphors 206y and 206r may provide the appearance of relatively warm white light output from the LED array 1000a. As used herein, “warm white” may refer to white light with a CCT of between about 2600K and 6000K, which is more reddish in color.

FIG. 10B illustrates an alternate configuration of a multi-chip LED arrays according to some embodiments of the present invention. Referring to FIG. 10B, an LED array 1000b includes a common substrate or submount 301 having first, second, and third die mounting regions 302a, 302b, and 302c. The die mounting regions 302a, 302b, and 302c are each configured to accept an LED chip, such as a light emitting diode, an organic light emitting diode, and/or a laser diode. As shown in FIG. 10B, LED chips 303b, 303g, and 303b′ are mounted on the die mounting regions 302a, 302b, and 302c of the submount 301, respectively. In some embodiments, the LED chips 303b, 303g, and 303b′ may be vertical devices including a cathode contact on one side the chip and an anode contact on an opposite side of the chip. The LED chip 303b may be configured to emit light within a blue wavelength range, the LED chip 303g may be configured to emit light within a green wavelength range, and the LED chip 303b″ may be configured to emit light within blue and/or ultraviolet wavelength ranges.

Still referring to FIG. 10B, the LED chip 303b′ is covered by a red-emitting wavelength conversion material 306r that is configured to receive the light emitted thereby and responsively emit light in a red wavelength range (e.g., about 590 nm to about 750 nm), such that the overall light output of the phosphor-converted LED chip 303b″ does not substantially include the light emitted by the LED chip 303b″ and provides the appearance of substantially monochromatic red light. For example the red-emitting phosphor 306r may be Y₂O₂S:Eu2+ in some embodiments. A color filter (not shown) may also be provided on the LED chip 303b″ to block light emitted therefrom that is not absorbed by the phosphor 306r. As such, the blue light emitted by the LED chip 303b, the green light emitted by the LED chip 303g, and the red light emitted by the phosphor-converted LED chip 303b″ may be combined such that the overall light output of the LED array 1000b provides the appearance of white light.

Although illustrated in FIGS. 10A and 10B with reference to multi-chip LED arrays including three LED chips, it will be understood that fewer or more LED chips and/or die mounting regions may be provided in accordance with some embodiments of the present invention. Also, while described generally with reference to phosphors as wavelength conversion materials, it will be understood that narrow emitter phosphors, broadband emitter phosphors, quantum dots, and/or other wavelength conversion materials may be used. Furthermore, additional wavelength conversion materials may be provided on each LED chip and/or multiple wavelength conversion materials may be provided on the same LED chip to provide the desired white light output.

Accordingly, embodiments of the present invention provide single-color wavelength-converted LEDs that provide emission characteristics comparable to conventional single-color LEDs, but with reduced sensitivity to thermal variation. In particular, such wavelength-converted LEDs provide reduced temperature sensitivity and improved efficiency at higher operating temperatures, for example, when operating at increased drive currents. Also, wavelength-converted LEDs according to some embodiments of the present invention may include a color filter configured to completely block the light emitted by the LED chip and/or wavelength conversion material(s) configured to completely absorb the light emitted by the LED chip, such that the overall light output of the wavelength-converted LEDs do not substantially include the primary light emitted by the LED chip. Embodiments of the present invention also include multi-chip LED arrays and/or lamps that include at least one single-color phosphor converted LED as described herein to provide a desired white light output.

While the above embodiments are described with reference to particular figures, it is to be understood that embodiments of the present invention may include additional and/or intervening layers or structures, and/or particular layers or structures may be deleted. More generally, the foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

That which is claimed:

1. A packaged light emitting device (LED), comprising:
an LED chip configured to emit light within a first wavelength range; and
a wavelength conversion material on the LED chip and configured to receive the light within the first wavelength range and responsively emit light within a second wavelength range different than the first wavelength range and corresponding to a red portion of a visible spectrum such that a light output of the packaged LED does not substantially include the light within the first wavelength range and provides an appearance of substantially monochromatic red light.

2. The packaged LED of claim 1, further comprising:
a color filter on the wavelength conversion material.

3. The packaged LED of claim 2, wherein the color filter comprises a layer on the wavelength conversion material such that the wavelength conversion material is between the color filter and the LED chip.

4. The packaged LED of claim 3 wherein the wavelength conversion material is configured to absorb at least a portion of the light within the first wavelength range, and wherein the color filter is configured to prevent passage of a remaining portion of the light within the first wavelength range that is not absorbed by the wavelength conversion material.

5. The packaged LED of claim 4, wherein the color filter is further configured to prevent passage of at least some of the light within the second wavelength range.

6. The packaged LED of claim 3, wherein the color filter is configured to block a portion of the light within the second wavelength range from passing therethrough.

7. The packaged LED of claim 2, further comprising:
an encapsulant layer on the LED chip,
wherein the color filter and the wavelength conversion material are included in the encapsulant layer.

8. The packaged LED of claim 1, wherein the wavelength conversion material comprises a thickness configured to completely absorb the light within the first wavelength range.

9. The packaged LED of claim 8, wherein the wavelength conversion material has a thickness of about 30 micrometers (μm) to about 75 μm.

10. The packaged LED of claim 1, further comprising:
a second wavelength conversion material on the LED chip and configured to receive the light within the first wavelength range and responsively emit light within a third wavelength range different than the first wavelength range such that the light output of the packaged LED provides the appearance of the substantially monochromatic light of the color corresponding to the second and third wavelength ranges.

11. The packaged LED of claim 10, wherein the first wavelength conversion material is configured to absorb at least a portion of the light within the first wavelength range, and wherein the second wavelength conversion material is configured to absorb a remaining portion of the light within the first wavelength range that is not absorbed by the first wavelength conversion material.

12. The packaged LED of claim 1, wherein the wavelength conversion material includes a narrow emitter phosphor comprising at least one of Eu3+, Cr, and/or Mn2+.

13. The packaged LED of claim 1, wherein the wavelength conversion material includes a broadband emitter phosphor comprising at least one of Eu2+ and Ce3+.

14. The packaged LED of claim 1, wherein the wavelength conversion material includes a quantum dot comprising at least one of ZnS, ZnSe, CdS, and CdSe.

15. The packaged LED of claim 1, wherein the LED chip comprises a Group III nitride-based active region.

16. The packaged LED of claim 15, wherein the first wavelength range comprises blue and/or ultraviolet light, and wherein the wavelength conversion material comprises at least one of (Ca,Sr,Ba)₂SiO₄:Eu2+, (Ca,Sr)SiAlN₃:Eu2+, CaSiN₂:Ce3+, CaSiN₂:Eu2+, (Sr,Ca,Ba)₂Si₅N₈:Eu2+, Alpha and Beta SiAlON, (Sr,Ca)S:Eu2+, and ZnGa₂S₄:Eu2+.

17. The packaged LED of claim 15, wherein the first wavelength range comprises green light, and wherein the wavelength conversion material comprises CaSiN₂:Ce3+.

18. The packaged LED of claim 1, wherein the light output of the packaged LED has a bandwidth of less than about 50 nm.

19. The packaged LED of claim 1, wherein the light output of the packaged LED comprises at least some light within the first wavelength range that is not visible to the human eye.

20. A multi-chip light emitting device (LED) array comprising a plurality of LEDs, wherein a light output of the LED array provides an appearance of white light, and wherein at least one of the plurality of LEDs comprises the packaged LED of claim 1.

21. A light emitting device (LED), comprising:
an LED chip configured to emit primary light within a first wavelength range;
a wavelength conversion material on the LED chip, the wavelength conversion material being configured to receive the primary light within the first wavelength range and responsively emit secondary light within a second wavelength range different than the first wavelength range; and
a color filter on the wavelength conversion material.

22. The LED of claim 21, wherein the color filter is configured to block primary light within the first wavelength range.

23. The LED of claim 22, wherein the color filter is configured to allow passage of the secondary light therethrough such that a light output of the LED provides an appearance of substantially monochromatic light of a color corresponding to the second wavelength range.

24. The LED of claim 21, wherein the light output of the packaged LED does not substantially comprise the primary light within the first wavelength range.

25. The LED of claim 21, wherein the wavelength conversion material is configured to absorb at least a portion of the primary light within the first wavelength range, and wherein the color filter is configured to prevent passage of a remaining portion of the primary light within the first wavelength range that is not absorbed by the wavelength conversion material.

26. The LED of claim 21, wherein the color filter comprises a layer on the wavelength conversion material such that the wavelength conversion material is between the color filter and the LED chip.

27. The LED of claim 21, wherein the color filter extends on opposing sidewalls of the LED chip.

28. The LED of claim 22, wherein the wavelength conversion material comprises a thickness configured to increase light emission at a desired wavelength range within the second wavelength range to increase a monochromaticity of a light output of the LED.

29. The LED of claim 21, wherein the LED chip comprises a GaN-based active region, and wherein the wavelength conversion layer comprises a red-emitting wavelength conversion material such that the light output of the LED provides an appearance of light within a red portion of a visible spectrum.

30. The LED of claim 21, wherein the LED chip comprises a GaN-based active region, and wherein the wavelength conversion layer comprises a green-emitting wavelength conversion material such that the light output of the LED provides an appearance of light within a green portion of a visible spectrum.

31. The LED of claim 21, wherein the wavelength conversion material is configured to absorb the primary light within the first wavelength range, and wherein the color filter is configured to block at least a portion of the secondary light within the second wavelength range.

32. A multi-chip light emitting device (LED) array, comprising:
a submount including first and second die mounting regions thereon;
a first LED chip mounted on the first die mounting region and configured to emit light within a first wavelength range;
a second LED chip mounted on the second die mounting region and configured to emit light within a second wavelength range; and
a wavelength conversion material on the first LED chip, wherein the wavelength conversion material is configured to receive the light within the first wavelength range and responsively emit light within a third wavelength range different than the first wavelength range and corresponding to a red portion of a visible spectrum such that a light output therefrom does not substantially include the light within the first wavelength range and provides an appearance of substantially monochromatic red light,
wherein an overall light output of the multi-chip LED array provides an appearance of white light.

33. The LED array of claim 32, further comprising:
a color filter on the wavelength conversion material, wherein the color filter is configured to block passage of the light within the first wavelength range and/or a portion of the light within the second wavelength range to provide the appearance of substantially monochromatic red light.

34. The LED array of claim 32, wherein the wavelength conversion material comprises at least one of a narrow emitter phosphor, a broadband emitter phosphor, and a quantum dot material.

35. The LED array of claim 32, wherein the wavelength conversion material comprises a first wavelength conversion material, and further comprising:
a second wavelength conversion material on the second LED chip, wherein the second wavelength conversion material is different than the first wavelength conversion material and is configured to receive the light within the second wavelength range and responsively emit light within a fourth wavelength range different than the second wavelength range.
